(19) United States
(12) Patent Application Publication
(10) Pub. No.: US 2024/0262019 A1
(43) Pub. Date: Aug. 8, 2024

(54) MOLDING APPARATUS HAVING WEDGE DRIVER

(71) Applicant: ASMPT Singapore Pte. Ltd., Singapore (SG)

(72) Inventors: Teng Hock KUAH, Singapore (SG); Kai Yew LEE, Singapore (SG); Ji Yuan HAO, Singapore (SG); Jian Jun CHEN, Singapore (SG); Yi LIN, Singapore (SG)

(21) Appl. No.: 18/107,121

(22) Filed: Feb. 8, 2023

(51) Int. Cl. B29C 43/18; B29C 43/00

(52) U.S. Cl. CPC B29C 43/183; B29C 43/003; B29C 2043/182; B29C 2043/3602; B29L 2031/34

(57) ABSTRACT

A molding apparatus includes a mold and a wedge structure. The mode has a first mold member and a second mold member configured to be movable towards the first mold member along a first direction, the first and second mold members cooperating in use to form a molding cavity for encapsulating an electronic component. The wedge structure has a first wedge member attached to the second mold member and a second wedge member configured to be in contact with the first wedge member and movable in a second direction perpendicular to the first direction to adjust contacting portions between a first contacting surface of the first wedge member and a second contacting surface of the second wedge member, thereby biasing the second mold member towards the first mold member to form the molding cavity, wherein at least one of the first and second contacting surfaces includes a first protection film attached thereon.

### FIELD OF THE INVENTION

The invention generally relates to molding apparatus for encapsulating electronic devices, especially semiconductor devices, and more specifically to a molding apparatus with a wedge driver or drivable wedge structure suitable for encapsulating electronic devices with different thicknesses.

### BACKGROUND

Typically, a molding apparatus for encapsulating electronic devices includes top and bottom mold members which combine to form a molding cavity for encapsulating the electronic devices. At least one of the mold members may include a drivable wedge structure configured to control the movement or adjust the position of the mold member attached to the wedge structure so as to form the molding cavity. Specifically, the wedge structure includes two wedge members which are arranged to be drivable to move relative to each other to control the movement of the mold member.

As the wedge structure is usually made from stainless steel, the contacting surfaces of the two wedge members may deteriorate or become worn due to constant frictional contact. Furthermore, when substantial scratches appear on the contacting surfaces of the wedge structure due to constant friction, the frictional force between the contacting surfaces will tend to increase, thereby affecting the accuracy of controlling the movement of the mold member with the wedge structure. In conventional molding apparatus, the wedge structures need to be reworked or replaced if obvious scratches appear, therefore the usual lifespan of a metal wedge structure is typically shorter than one month. This will reduce the efficiency of the molding apparatus and increase maintenance costs.

To solve the aforesaid problem, one prior art approach is to apply lubricant/grease on the contacting surfaces of the wedge structure. However, the application of the lubricant/grease will significantly decrease the frictional forces between the contacting surfaces of the wedge structure, which may also lead to another issue of bleeding of encapsulant during encapsulation. Specifically, as the coefficient of friction of the contacting surfaces will decrease when the lubricant/grease is applied, unwanted sliding between the two wedge members of the wedge structure may occur when encapsulant is introduced into the molding cavity and an encapsulation pressure is experienced by the mold members, thereby causing bleeding of encapsulant from the molding cavity.

Another prior art method for protecting the contacting surfaces of the wedge structures is to apply a coating thereon. However, the coating cannot last for very long due to constant friction. Once the coating is worn out, a de-coating process is needed before re-coating the surfaces, and thus the repair costs will be further increased.

It would therefore be beneficial to provide a new solution for protecting the contacting surfaces of the wedge structure in a molding apparatus that can address at least one of the issues faced by the prior art approaches mentioned above.

### SUMMARY OF THE INVENTION

It is thus an object of the invention to seek to provide an improved molding apparatus having a wedge driver or drivable wedge structure. In this molding apparatus, at least one protection film is provided to protect the contact surfaces of the wedge structure.

According to a first aspect of the present invention, there is provided a molding apparatus. The molding apparatus includes a mold having a first mold member and a second mold member configured to be movable towards the first mold member along a first direction, the first and second mold members cooperating in use to form a molding cavity for encapsulating an electronic component, a wedge structure having a first wedge member attached to the second mold member and a second wedge member configured to be in contact with the first wedge member and movable in a second direction perpendicular to the first direction to adjust contacting portions between a first contacting surface of the first wedge member and a second contacting surface of the second wedge member, thereby biasing the second mold member towards the first mold member to form the molding cavity, wherein at least one of the first and second contacting surfaces includes a first protection film attached thereon.

Preferably, each of the first and second contacting surfaces includes a first protection film. In other words, there are two first protection films that are respectively attached to the first and the second contacting surfaces such that both the first and second contacting surfaces are protected properly.

In some embodiments, the molding apparatus further comprises a supporting base on which the wedge structure is disposed, the wedge structure having a third contacting surface and the supporting base having a fourth contacting surface in contact with the third contacting surface of the wedge structure, wherein at least one of the third and fourth contacting surface includes a second protection film attached thereon. Preferably, both the third and fourth contacting surfaces include the second protection film. In other words, there are two second protection films that are respectively attached to the third and fourth contacting surfaces such that both the third and fourth contacting surfaces are protected properly.

In some embodiments of the invention, the protection film, i.e., the first and/or the second protection film may be selected from the group consisting of polyimide (PI) film, ethyl tetra fluoro ethylene (ETFE) film, polytetrafluoroethylene (PTFE) film and polyester film.

Preferably, the protection film has a coefficient of friction in a range of 0.01 to 0.65. Also, the protection film should be configured to withstand a temperature in a range of 150° C. to 250° C.

In one embodiment of the invention, the first protection film is attached to the second contacting surface of the second wedge member and the second protection film is attached to the third contacting surface of the second wedge member.

In order to provide an effective protection film to the contacting surfaces of the wedge structure without affecting the relative motion between the first and second wedge members, and the motion of the second wedge member on the supporting base, it is also very critical to provide a proper way for installing the protection film on the contacting surfaces. In some embodiments, the molding apparatus further includes a fixing mechanism configured for clipping two free ends of a sheet of protection film to cover two contacting surfaces of the second wedge member of the molding apparatus. In one embodiment, the sheet of protection film is folded so as to form a space to allow the second wedge member to be inserted into the space, such that the same sheet of protection film is located between the first and second contacting surfaces and between the third and fourth contacting surfaces.

In one embodiment, the fixing mechanism may include a first clipping bar and a second clipping bar between which the two free ends of the sheet of protection film is disposed and at least one fixing component, e.g., screws, configured to pass through mounting holes on the first and second clipping bars so as to lock the two free ends of the sheet of protection film with the first and second clipping bars. To provide tension to the sheet of protection film attached to the second and third contacting surfaces of the second wedge member, the molding apparatus may further include a resilient mechanism that is installed on the sheet of protection film through the fixing mechanism. The resilient mechanism may include a resilient member, and a latching mechanism configured for installing the resilient member to the fixing mechanism with a fixing member, e.g., screws.

According to a second aspect of the present invention, there is provided a method for molding an electronic component. The method comprises: providing a molding apparatus comprising a mold having a first mold member and a second mold member configured to be movable towards the first mold member along a first direction, and a wedge structure having a first wedge member attached to the second mold member and a second wedge member configured to be in contact with the first wedge member and movable in a second direction perpendicular to the first direction, and moving the second wedge member of the wedge structure in the second direction to adjust contacting portions between a first contacting surface of the first wedge member and a second contacting surface of the second wedge member, thereby biasing the second mold member towards the first mold member to form a molding cavity for encapsulating an electronic component, wherein a first protection film is attached to the first or second contacting surface.

In some embodiments, the method further comprises a step of attaching the first protection film to at least one of the first contacting surface of the first wedge member and the second contacting surface of the second wedge member. Preferably, the first protection film is attached to both the first and the second contacting surfaces.

In some embodiments, the method further comprises a step of attaching a second protection film to at least one of a third contacting surface of the wedge structure and a fourth contacting surface of a supporting base that is in contact with the third contacting surface on which the wedge structure is disposed. Preferably, the step of attaching the second protection film includes attaching two second protection films to the third and fourth contacting surfaces respectively.

In one embodiment, the step of attaching the first protection film comprises: attaching the first protection film to the second contacting surface of the second wedge member, and the step of attaching the second protection film comprises: attaching the second protection film to the third contacting surface of the wedge structure.

Preferably, the step of attaching the first and second protection films may comprise: folding a sheet of protection film to form a space to allow the second wedge member to be inserted into the space; clipping two free ends of the folded sheet of protection film with a fixing mechanism; and inserting the second wedge member into the space formed by the folded sheet of protection film such that both the second contacting surface and the third contacting surface of the second wedge member are covered by the protection film.

The two free ends of the sheet of the protection film may be clipped by the following steps: disposing the two free ends of the sheet of protection film between a first clipping bar and a second clipping bar of the fixing mechanism and passing at least one fixing component through mounting holes on the first and second clipping bars so as to lock the two free ends of the sheet of protection film with the first and second clipping bars. The method may further include a step of installing a resilient mechanism on the sheet of the protection film through the fixing mechanism to provide tension to the sheet of protection film attached to both the second and third contacting surfaces of the second wedge member of the wedge structure.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1 shows a front view of a molding apparatus according to one embodiment of the invention.

FIG. 2A shows a front view of an initial arrangement of the molding apparatus as shown in FIG. 1 when the molding apparatus is in use according to one embodiment of the invention.

FIG. 2B shows a front view of the molding apparatus as shown in FIG. 1 showing the formation of a molding cavity for introducing an encapsulant for encapsulation.

FIG. 2C shows a front view of the molding apparatus as shown in FIG. 1 when the encapsulant is introduced into the molding cavity and an encapsulation pressure is experienced.

FIG. 3A shows a force analysis when a bottom wedge member of the molding apparatus is driven to move in a direction D2 as shown in FIG. 2A.

FIG. 3B shows a force analysis when the bottom wedge member of the molding apparatus is pushed to move in a direction D2′ opposite the direction D2 by a packing force or encapsulation pressure F4 as shown in FIG. 2C.

FIG. 4 shows a process for installing a sheet of protection film on contacting surfaces of a bottom wedge member of the molding apparatus according to one embodiment of the invention.

FIG. 5 shows a front view of a molding machine including two molding apparatus according to one embodiment of the invention.

FIG. 6A and FIG. 6B respectively show relationships between vertical travel distances of the wedge structures of the two molding apparatus and horizontal travel distances thereof when the molding machine including the two molding apparatus in FIG. 5 is used for simultaneously encapsulating devices with different thicknesses.

In the drawings, like parts are denoted by like reference numerals.

### DETAILED DESCRIPTION OF THE PREFERRED EMBODIMENTS OF THE INVENTION

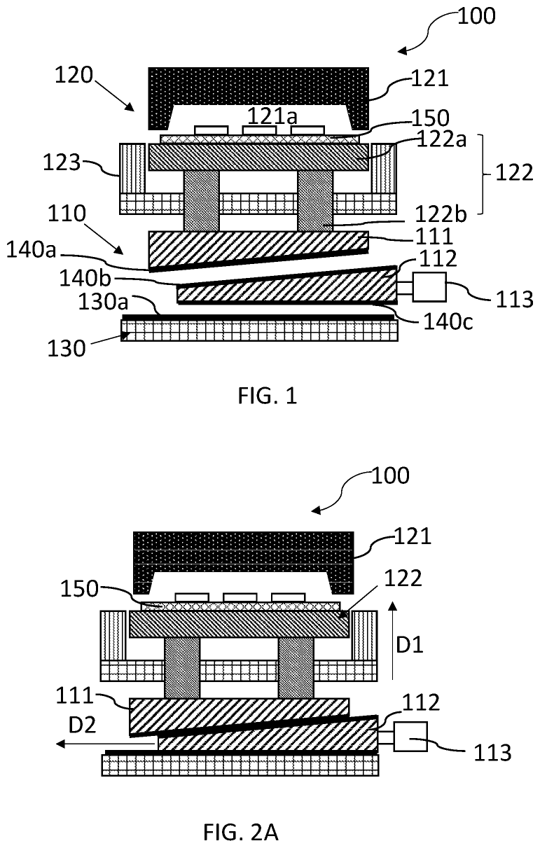

FIG. 1 shows a front view of a molding apparatus 100 according to one embodiment of the invention. The molding apparatus 100 includes a drivable wedge structure 110 and a mold 120. In use, the molding apparatus 100 is disposed on a supporting base 130. Specifically, the mold 120 is connected to the wedge structure 110 and the wedge structure 110 is disposed on the supporting base 130. The molding apparatus 100 further includes protection films that are attached to contacting surfaces of the wedge structure 110.

The wedge structure 110 includes a first wedge member 111, a second wedge member 112 and a wedge driving mechanism 113 attached to the second wedge member 112. In this embodiment, the first wedge member 111 is a top wedge member and the second wedge member 112 is a bottom wedge member. In use, the second wedge member 112 is resting on the supporting base 130. The wedge driving mechanism 113 is in the form of a pneumatic cylinder. Alternatively, the wedge driving mechanism 113 may be in the form of other types of motors in other embodiments of the invention. As shown in FIG. 1, the wedge structure 110 includes first and second contacting surfaces between the first and the second wedge members 111, 112. Specifically, the first contacting surface is the bottom surface of the first wedge member 111, and the second contacting surface is the top surface of the second wedge member 112 which contacts the first contacting surface when the molding apparatus 100 is in use. The wedge structure 110 further includes a third contacting surface that is the bottom surface of the bottom wedge member 112 which is in contact with a fourth contacting surface, i.e., the top surface, of the supporting base 130 when the molding apparatus 100 is in use. In this embodiment, each of the first to fourth contacting surfaces includes a protection film attached thereon. The four protection films include a first pair of protection films 140a, 140b located between the first and second wedge members 111, 112, and a second pair of protection films 140c, 130a located between the second wedge member 112 and the supporting base 130.

It is to be appreciated by a person skilled in the art, the molding apparatus in some embodiments may only include one of the first pair of protection films 140a, 140b to protect the first and second contacting surfaces between the first and second wedge members 111, 112. In some other embodiments, the molding apparatus may further include just one of the third and fourth protection films 140c, 130a to protect the third and fourth contacting surfaces between the second wedge member 112 and the supporting base 130.

The mold 120 includes a first mold member 121 and a second mold member 122. In this embodiment, the first mold member 121 is a fixed top mold member having a molding cavity 121a. The second mold member 122 is a movable member which includes a mold plate 122a on which a device 150 to be encapsulated is disposed, and a bottom connecting portion 122b in the form of multiple legs extending from a bottom surface of the mold plate 122a. The connecting portion 122b is configured to connect or attach the second mold member 122 to the wedge structure 110. As shown in FIG. 1, the connecting portion 122b is supported on or attached to a top surface of the first wedge member 111.

In this embodiment, the mold 120 further includes a guide frame 123 configured to house and guide movement of the second mold member 122. The guide frame 123 forms an enclosure allowing the second mold member 122 to be movable along a direction parallel to the direction of a clamping pressure. In this embodiment, the second mold member 122 may be moved up and down in a vertical direction. The second mold member 122 is movable towards the first mold member 121 so as to form an enclosed molding cavity between the first and second mold members 121, 122. The guide frame 123 also includes at least one opening to allow the connecting portion 122b to pass through such that the connecting portion 122b is attached to the first wedge member 111. In this embodiment, as shown in FIG. 1, the guide frame 123 includes multiple openings configured to allow the legs of the connecting portion 122b to pass through.

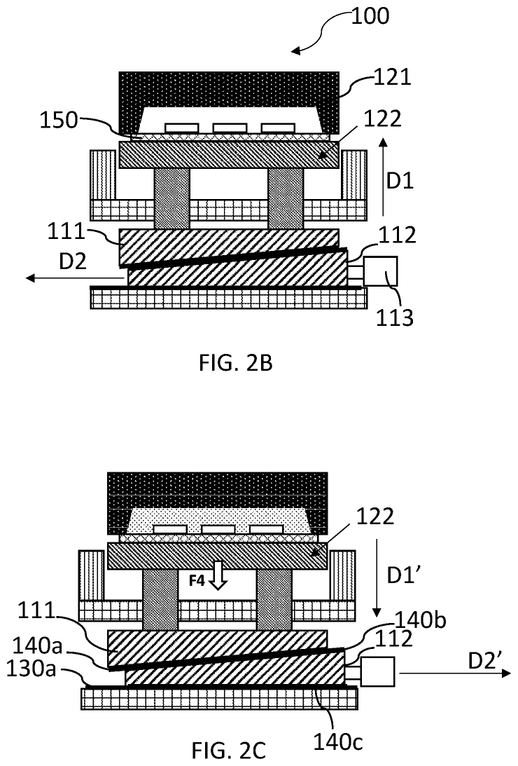

FIG. 2A to FIG. 2C show a process of encapsulating the device 150 with the molding apparatus 100 according to one embodiment of the invention. FIG. 2A shows a front view of an initial arrangement of the molding apparatus 100 when the molding apparatus 100 is in use according to one embodiment of the invention. As shown in FIG. 2A, the first mold member 121 is fixedly positioned at a predetermined first clamping position. The bottom surface of the first wedge member 111 and the top surface of the second wedge member 112 are partially overlapping. To form the molding cavity for encapsulation, the pneumatic cylinder 113 drives the second wedge member 112 to move along a driving direction D2 perpendicular to a clamping direction D1 such that the second mold member 122 attached to the first wedge member 111 is pushed to move up along the clamping direction D1. As shown in FIG. 2A, the clamping direction D1 in this embodiment is a vertical direction and the driving direction D2 is a horizontal direction.

FIG. 2B shows a front view of the molding apparatus 100 when the molding cavity for holding encapsulant for encapsulation is formed, i.e., when the second mold member 122 moves to a second clamping position. In this embodiment, the second mold member 122 is moved up until the device 150 placed thereon contacts the first mold member 121. After that, the second wedge member 112 is further driven to move in the direction D2 by the pneumatic cylinder 113 so that the second mold member 122 is further pushed/biased towards the first mold member 121 to form an enclosed molding cavity for containing encapsulant for molding the device 150. Preferably, the second wedge member 112 is driven to move along the driving direction D2 until a clamping force between the first and second mold members 111, 112 reaches a preset value. Once the molding cavity is formed with the requisite clamping pressure, an encapsulant is introduced into the enclosed space between the first and second mold members 121, 122, as shown in FIG. 2C. With the introduction of the encapsulant, an encapsulation pressure F4 along a direction D1′ opposite the direction D1 is applied to the first mold member 111 through the second mold member 112. Accordingly, the second wedge member 112 may be pushed to move in a release direction D2′ when the encapsulation pressure F4 is applied if the friction between the first and second contacting surfaces of the first and second wedge members 111, 112 is not sufficient to prevent forced sliding between these two wedge members 111, 112 during encapsulation.

Therefore, it is important to select and attach appropriate protection films 140a, 140b, 140c, 130a to the contacting surfaces of the wedge structure 100 and the top surface of the supporting base 130. The frictional forces between the contacting surfaces must be small enough to facilitate the movement of the second wedge member 112 relative to the first wedge member 111 when the second wedge member 112 is driven by the pneumatic cylinder 113, so as to push the second mold member 122 upwards. They must also be sufficient to prevent relative movement between the first and second wedge members 111, 112 to avoid bleeding of encapsulant when the second mold member 122 experiences the encapsulation pressure during molding. Selection of the protection film(s) will be explained below.

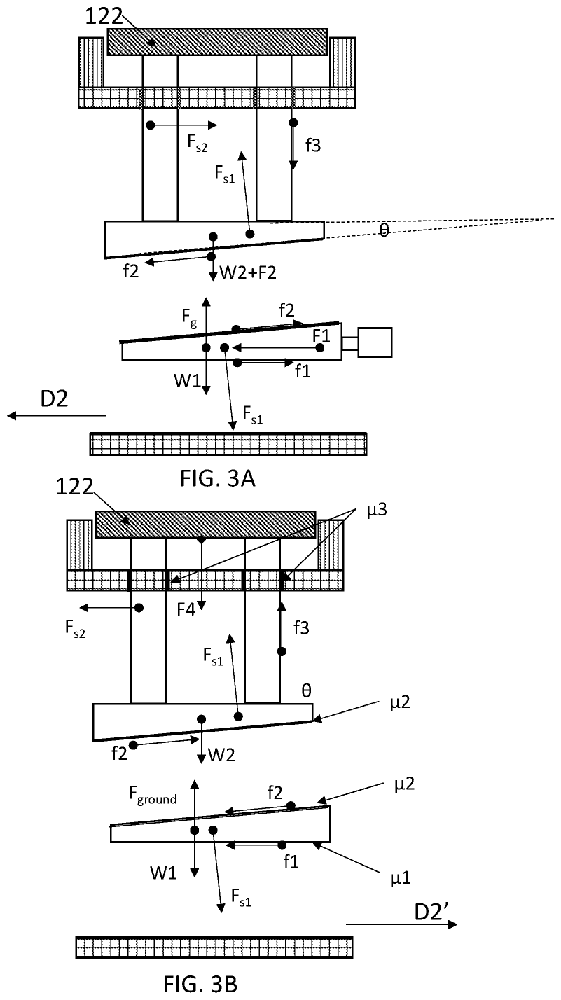

FIG. 3A shows a force analysis when the second wedge member 112 is driven to move in the direction D2 as shown in FIG. 2A. This is a searching stage during preparation for molding. In this scenario, the pneumatic cylinder 113 applies a driving force F1 to the second wedge member 112 along the driving direction D2 and the second wedge member 112 is moved along the driving direction D2 until the second mold member 122 reaches its final clamping position.

For the first wedge member 111, the force analysis is indicated in the following equations:

$$\sum {F}_{x} = {F}_{s 1} \times sin θ + f 2 \times cos θ - {F}_{s 2} = 0$$

$$\sum {F}_{y} = {F}_{s 1} \times cos θ - f 2 \times sin θ - f 3 - W 2 - F 2 = 0$$

where Fₛ₁ is the pressure force applied to the first wedge member 111 by the second wedge member 112 in the direction perpendicular to the contacting surface, F2 is a lifting force generated and applied to the first wedge member 111, f2=Fₛ₁×μ₂, f3=Fₛ₂×μ₃, and W2 is a total weight of the first wedge member 111 and the fixed mold member 122. Accordingly Fₛ₁ and F2 can be expressed by the following equations:

$${F}_{s 1} \times sin θ + {F}_{s 1} \times {μ}_{2} \times cos θ - {F}_{s 2} = 0$$

$$F 2 = {F}_{s 1} \times cos θ - {F}_{s 1} \times {μ}_{2} \times sin θ - {F}_{s 2} \times {μ}_{3} - W 2 = {F}_{s 1} cos θ - {F}_{s 1} {μ}_{2} sin θ - ( {F}_{s 1} sin θ + {F}_{s 1} {μ}_{2} cos θ ) {μ}_{3} - W 2$$

$${F}_{s 1} = \frac{F 2 + W 2}{cos θ - {μ}_{2} sin θ - {μ}_{3} sin θ - {μ}_{2} {μ}_{3} cos θ}$$

For the second wedge member 112, the force analysis is represented by the following equations:

$$\sum {F}_{x} = F 1 - {F}_{s 1} \times sin θ - f 1 - f 2 \times cos θ = 0$$

$$\sum {F}_{y} = {F}_{g} - {F}_{s 1} \times cos θ - W 1 + f 2 \times sin θ = 0$$

where F_{g} is the supporting force provided by the supporting base 130, f1=F_{g}×μ₁, f2=Fₛ₁×μ₂, and W1 is the weight of the second wedge member 112. Accordingly F1 can be calculated according to the following equations:

$${F}_{g} = {F}_{s 1} \times cos θ + W 1 - {F}_{s 1} \times {μ}_{2} \times sin θ$$

$$F 1 = {F}_{s 1} \times sin θ + {F}_{g} \times {μ}_{1} + {F}_{s 1} \times {μ}_{2} \times cos θ = {F}_{s 1} sin θ + ( {F}_{s 1} cos θ + W 1 - {F}_{s 1} {μ}_{2} sin θ ) {μ}_{1} + {F}_{s 1} {μ}_{2} cos θ$$

$${F}_{s 1} = \frac{F 2 + W 2}{cos θ - {μ}_{2} sin θ - {μ}_{3} sin θ - {μ}_{2} {μ}_{3} cos θ}$$

FIG. 3B shows a force analysis when the second wedge member 112 is forced to move in the direction D2′ opposite the driving direction D2 by a packing force or encapsulation pressure F4 as shown in FIG. 2C. In this scenario, the pneumatic cylinder 113 has stopped moving and the movement of the second wedge member 112 is forced by the encapsulation pressure F4.

For the first wedge member 111, the force analysis is indicated in the following equations:

$$\sum {F}_{x} = 0 = {F}_{s 1} \times sin θ - f 2 \times cos θ + {F}_{s 2}$$

$$\sum {F}_{y} = 0 = {F}_{s 1} \times cos θ + f 2 \times sin θ + f 3 - W 2 - F 4$$

where

$$f 2 = {F}_{s 1} \times {μ}_{2}$$

$$f 3 = {F}_{s 2} \times {μ}_{3}$$

W2 is the total weight of the first wedge member 111 and the fixed molding mold member 122. Accordingly F4 can be calculated according to the following equations:

$${F}_{s 1} \times sin θ - {F}_{s 1} \times {μ}_{2} \times cos θ + {F}_{s 2} = 0$$

$$F 4 = {F}_{s 1} \times cos θ + {F}_{s 1} \times {μ}_{2} \times sin θ + {F}_{s 2} \times {μ}_{3} - W 2$$

$$F 4 = {F}_{s 1} cos θ + {F}_{s 1} {μ}_{2} sin θ + ( {F}_{s 1} sin θ - {F}_{s 1} {μ}_{2} cos θ ) {μ}_{3} - W 2$$

For the second wedge member 112, the force analysis is indicated in the following equations:

$$\sum {F}_{x} = - {F}_{s 1} \times sin θ + f 1 + f 2 \times cos θ = 0$$

$$\sum {F}_{y} = {F}_{g} - {F}_{s 1} \times cos θ - W 1 - f 2 \times sin θ = 0$$

where

$$f 1 = {F}_{g} \times {μ}_{1}$$

$$f 2 = {F}_{s 1} \times {μ}_{2}$$

W1 is the weight of the second wedge member 112. Accordingly F1 can be calculated according to the following equations:

$$- {F}_{s 1} \times sin θ + {F}_{g} \times {μ}_{1} + {F}_{s 1} \times {μ}_{2} \times cos θ = 0$$

$${F}_{g} = {F}_{s 1} \times cos θ + W 1 + {F}_{s 1} \times {μ}_{2} \times sin θ$$

$${F}_{s 1} = \frac{{μ}_{1} W 1}{sin θ - {μ}_{1} cos θ - {μ}_{1} {μ}_{2} sin θ - {μ}_{2} cos θ}$$

To simplify the calculation, it is assumed that μ₁=μ₂=μ, and μ₃ should be very small, e.g., 0.05, so that the following equation may be used to determine the value of μ:

$$a {μ}^{2} + b μ + c = 0$$

### Where

$$a = W 1 sin θ - W 1 {μ}_{3} cos θ + ( F 4 + W 2 ) sin θ$$

$$b = W 1 cos θ + W 1 {μ}_{3} sin θ + 2 ( F 4 + W 2 ) cos θ$$

$$c = ( F 4 + W 2 ) sin θ$$

The values of θ, W1, W2, and F4 of the wedge structure 110 that has been constructed are already known, and the appropriate coefficient of friction u can be determined according to the equations above. Using this method, a range of appropriate coefficients of friction of the protection films 140a, 140b, 140c, 130a are obtained, which are from 0.01 to 0.65. Besides the coefficients of friction, the protection films 140a, 140b, 140c, 130a used in the present invention must also be capable of withstanding temperatures of up to 300° C., more preferably temperatures in the range of 150° C. to 250° C.

According to the determined range of appropriate coefficients of friction and requirements for working temperatures, the following tapes or films may be used as protection films 140a, 140b, 140c, 130a in this invention:
Polyimide film (PI film)
ETFE film
PTFE film
Polyester film

In one embodiment, the protection films 140a, 140b, 140c, 130a are made from PI film. According to the experimental results as set out in table 1 below, the applicable coefficients of friction (both the coefficients of kinetic and static friction) of PI film are similar to that of steel surfaces of the wedge ember.

TABLE 1

| Surface | Static CoF | Kinetic CoF | Remarks |
|---|---|---|---|
| Steel to steel | 0.5~0.8 | 0.42 | |
| Steel to steel | 0.15~0.2 | | With necessary lubrica [symbol] |
| With PI film | 0.63 | 0.48 | |

[symbol]

indicates data missing or illegible when filed

Thus, PI film has the following advantages besides protecting the contacting surfaces of the wedge structure 110 and supporting base 130:
PI film will not hinder the movement of the second wedge member 112 during a searching stage of the molding process.
PI film is effective to prevent the second wedge member 112 from moving along the direction D2′ when an encapsulation pressure is applied to the second wedge member 112 through the movable molding mold member 122 and the first wedge member 111 during a clamping stage of the molding process.
PI film is able to withstand high working temperatures, e.g., up to 300° C., required for molding and also high encapsulation pressure required for the molding apparatus.
The cost of making and installing the protection film is low.
It is easy to replace the protection films when necessary, thereby reducing the maintenance costs.

After selecting an appropriate protection film, it is also important to properly attach the protection films on the contacting surfaces. Below, a method for installing the protection films on the contacting surfaces of the wedge structure 110 will be explained.

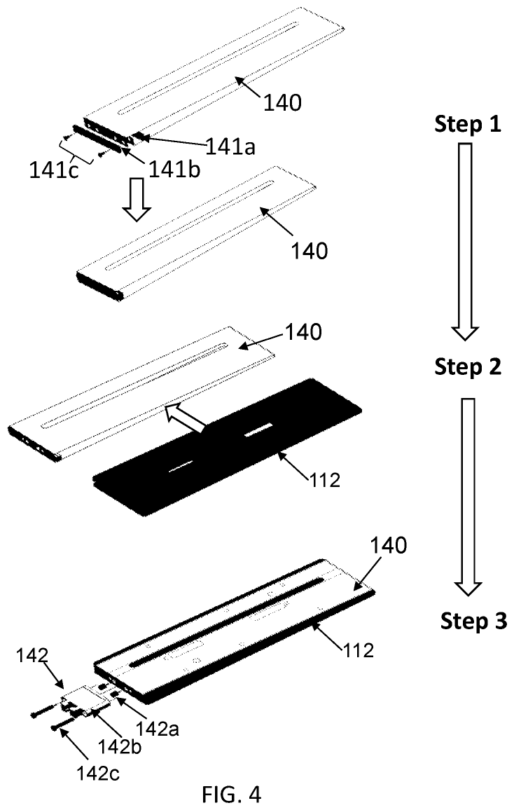

FIG. 4 shows a process for installing a protection film on contacting surfaces of the second wedge member 112 according to one embodiment of the invention.

At Step 1, a sheet of protection film 140 is folded to form a space to allow the second wedge member 112 to be inserted such that the contacting surfaces of the second wedge member 112 are covered by the protection film 140, and the two free ends of the folded protection film 140 are clipped by a fixing mechanism 141a, b, c.

Referring to FIG. 4, the fixing mechanism 141 may include a first clipping bar 141a, a second clipping bar 141b and at least one fixing component 141c, e.g., screw, for clipping the two free ends of the protection film 140 with the first and second clipping bars 141a, 141b. The first and second clipping bars 141a, 141b may be metal bars.

At Step 2, the second wedge member 112 is inserted into the space formed by the folded protection film 140 so that the contacting surfaces of the second wedge member 112 are tightly covered by the protection firm 140 without wrinkles and overlapping.

At Step 3, a resilient mechanism 142 is installed on the fixing mechanism 141 to provide tension to the protection film 140 covering the contacting surfaces of the second wedge member 112.

As shown in FIG. 4, the resilient mechanism 142 may include a resilient member 142a, e.g., springs, and a latching mechanism 142b for installing the resilient member 142a to the fixing mechanism 141 with fixing member 142c, e.g., screws.

It should be appreciated by a person skilled in the art that the method described above may also be used to install a protection film on a contacting surface of the first wedge member 111. The only difference is that the protection film is only required to cover the bottom surface of the first wedge member 111 since only its bottom surface is to be in contact with the second wedge member 112.

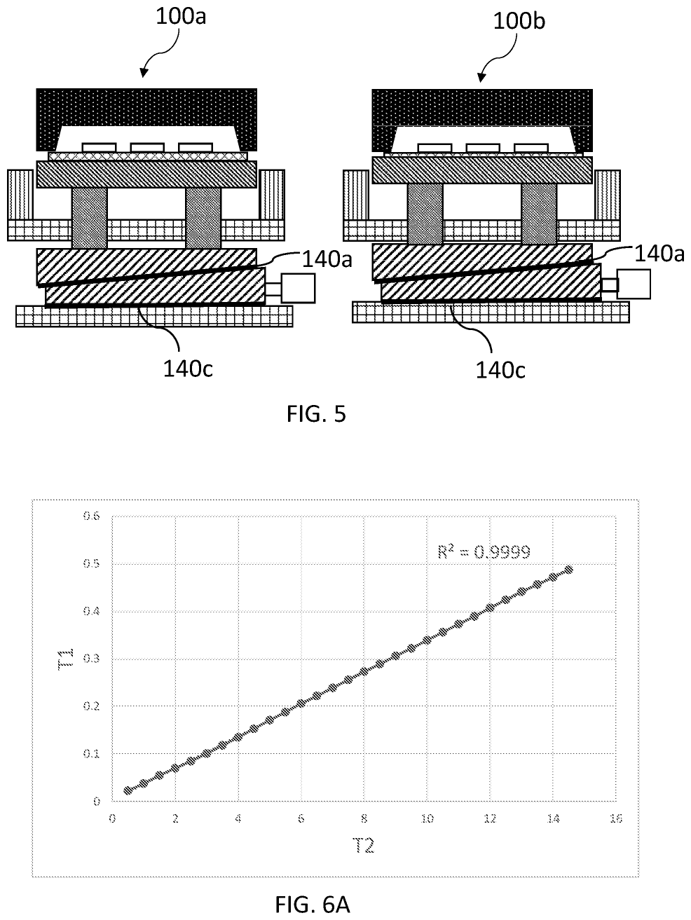

In practice, the molding machine may include two molding apparatus that operate simultaneously. For instance, the two molding apparatus are arranged side by side to form a left molding cavity and a right molding cavity. FIG. 5 shows a front view of a molding machine including two molding apparatus 100a, 100b according to one embodiment of the invention. The wedge structure of each molding apparatus 100a, 100b may include a first protection film 140a attached to the top wedge member of the wedge structure and a second protection film 140c attached to the bottom surface of the bottom wedge member 112 as shown in FIG. 5. With the wedge structures, the two molding apparatus 100a, 100b of the molding machine may handle devices with different thicknesses simultaneously.

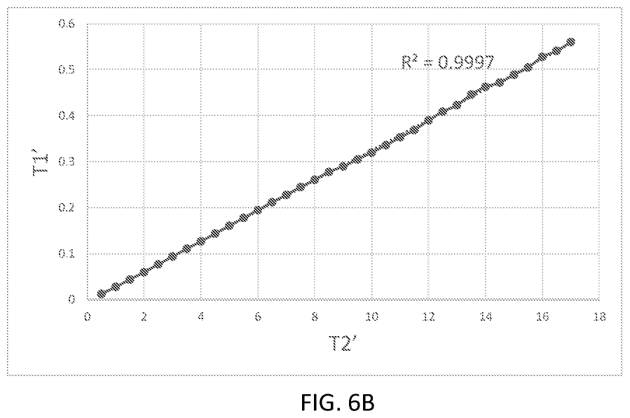

The test results when the molding apparatus 100a, 100b are used to encapsulate two set of devices with different thicknesses simultaneously show that no bleeding of encapsulant takes place in the molding apparatus 100a, 100b. The wedge structures of the respective molding apparatus 100a, 100b show good linearity as shown in FIG. 6A and FIG. 6B. FIG. 6A shows the relationship between a vertical travel distance T1 of the wedge structure of the molding apparatus 100a and a horizontal travel distance T2 thereof when the molding machine in FIG. 5 is used for encapsulating devices with different thicknesses simultaneously. FIG. 6B shows the relationship between a vertical travel distance T1′ of the wedge structure of the molding apparatus 100b and a horizontal travel distance T2′ thereof when the molding machine in FIG. 5 is used for encapsulating devices with different thicknesses simultaneously. As shown in FIG. 6A and FIG. 6B, the linearities R² of the wedge structures of the molding apparatus 100a, 100b are close to 1, which are 0.9999 and 0.9997 respectively.

As will be appreciated from the above description, embodiments of the invention provide a molding apparatus including at least one protection film attached to at least one of the contacting surfaces between the first and second wedge members. The molding apparatus may further include at least one protection film attached to the contacting surfaces between the supporting base and the second wedge member. The protection film(s) is provided to effectively protect the contacting surfaces from wear and tear caused due to constant frictional contact during the molding process without restricting the movement of the second wedge member relative to the first wedge member, thereby prolonging the lifetime of the molding apparatus. Also, the protection film(s) is effective for preventing the second wedge member from being forced to slide along a horizontal direction when an encapsulation pressure is transferred to the second wedge member so as to avoid bleeding of the encapsulant. Further, as the cost of the protection film is low and it is easy to replace a worn protection film with a new one, the maintenance costs of the molding apparatus will be greatly reduced.

Although the present invention has been described in considerable detail with reference to certain embodiments, other embodiments are possible. Therefore, the spirit and scope of the appended claims should not be limited to the description of the embodiments contained herein.

1. A molding apparatus comprising:
a mold having a first mold member and a second mold member configured to be movable towards the first mold member along a first direction, the first and second mold members cooperating in use to form a molding cavity for encapsulating an electronic component,
a wedge structure having a first wedge member attached to the second mold member and a second wedge member configured to be in contact with the first wedge member and movable in a second direction perpendicular to the first direction to adjust contacting portions between a first contacting surface of the first wedge member and a second contacting surface of the second wedge member, thereby biasing the second mold member towards the first mold member to form the molding cavity, wherein at least one of the first and second contacting surfaces includes a first protection film attached thereon.

2. The molding apparatus according to claim 1, further comprising:
a supporting base on which the wedge structure is disposed, the second wedge member having a third contacting surface and the supporting base having a fourth contacting surface in contact with the third contacting surface, wherein at least one of the third and fourth contacting surfaces includes a second protection film attached thereon.

3. The molding apparatus according to claim 2, wherein the protection film has a coefficient of friction in a range of 0.01 to 0.65.

4. The molding apparatus according to claim 3, wherein the protection film is configured to withstand a temperature in a range of 150° C. to 250° C.

5. The molding apparatus according to claim 2, wherein the protection film is selected from the group consisting of polyimide (PI) film, ethyl tetra fluoro ethylene (ETFE) film, polytetrafluoroethylene (PTFE) film and polyester film.

6. The molding apparatus according to claim 2, wherein the first protection film is attached to the second contacting surface of the second wedge member, and the second protection film is attached to the third contacting surface of the second wedge member.

7. The molding apparatus according to claim 6, further comprising a fixing mechanism configured for clipping two free ends of a sheet of protection film to be attached to the second and third contacting surfaces.

8. The molding apparatus according to claim 7, wherein the sheet of protection film is folded so as to form a space to allow the second wedge member to be inserted into the space, such that the same sheet of protection film is attached to the second and third contacting surfaces.

9. The molding apparatus according to claim 7, wherein the fixing mechanism comprises:
a first clipping bar and a second clipping bar between which the two free ends of the sheet of protection film are disposed and
at least one fixing component configured to pass through mounting holes on the first and second clipping bars so as to lock the two free ends of the sheet of protection film with the first and second clipping bars.

10. The molding apparatus according to claim 7, further comprising a resilient mechanism that is installed on the protection film through the fixing mechanism to provide tension to the sheet of protection film attached to the second and fourth contacting surfaces.

11. A method for molding an electronic component, comprising:
providing a molding apparatus comprising a mold having a first mold member and a second mold member configured to be movable towards the first mold member along a first direction, and a wedge structure having a first wedge member attached to the second mold member and a second wedge member configured to be in contact with the first wedge member and movable in a second direction perpendicular to the first direction, and
moving the second wedge member of the wedge structure in the second direction to adjust contacting portions between a first contacting surface of the first wedge member and a second contacting surface of the second wedge member, thereby biasing the second mold member towards the first mold member to form a molding cavity for encapsulating the electronic component, wherein the first or second contacting surface includes a first protection film attached thereon.

12. The method according to claim 11, further comprising:
attaching the first protection film to at least one of the first and second contacting surfaces.

13. The method according to claim 11, further comprising:
attaching a second protection film to at least one of a third contacting surface of the second wedge member and a fourth contacting surface of a supporting base that is in contact with the third contacting surface on which the wedge structure is disposed.

14. The method according to claim 13, wherein the step of attaching the first protection film comprises: attaching the first protection film to the second contacting surface of the second wedge member, and the step of attaching the second protection film comprises: attaching the second protection film to the third contacting surface of the second wedge member.

15. The method according to claim 14, wherein the step of attaching the first and second protection films comprises: folding a sheet of protection film to form a space to allow the second wedge member to be inserted into the space; clipping two free ends of the folded sheet of protection film with a fixing mechanism; and inserting the second wedge member into the space formed by the folded sheet of protection film such that both the second contacting surface and the third contacting surface of the second wedge member are covered by the protection film.

16. The method according to claim 15, wherein the step of clipping the two free ends of the sheet of protection film comprises:
disposing the two free ends of the sheet of protection film between a first clipping bar and a second clipping bar of the fixing mechanism, and
passing at least one fixing component through mounting holes on the first and second clipping bars so as to lock the two free ends of the sheet of protection film with the first and second clipping bars.

17. The method according to claim 16, further comprising: installing a resilient mechanism on the sheet of the protection film through the fixing mechanism to provide tension to the protection film attached to both the second and third contacting surfaces of the wedge structure.
